(19) United States
(12) Patent Application Publication
(10) Pub. No.: US 2026/0343116 A1
(43) Pub. Date: Oct. 29, 2026

(54) IMAGE SENSING DEVICE AND IMAGING DEVICE INCLUDING THE SAME

(71) Applicant: SK hynix Inc., Icheon-si (KR)

(72) Inventor: Hyung June YOON, Icheon-si (KR)

(21) Appl. No.: 19/350,465

(22) Filed: Oct. 6, 2025

(30) Foreign Application Priority Data
Apr. 23, 2025 (KR) 10-2025-0053095

(51) Int. Cl. H04N 25/65; H04N 25/773; H04N 25/76

(52) U.S. Cl. CPC H04N 25/65; H04N 25/773; H04N 25/7795

(57) ABSTRACT

Image sensing devices and imaging devices including the image sensing devices are discloses. In an embodiment, an image sensing device includes: a plurality of first pixels configured to convert light into photocharge and arranged in a first row of a pixel array; a first feedback signal line configured to transmit a feedback signal from the plurality of first pixels; a first feedback amplifier configured to compare a feedback signal received from the first feedback signal line with a reference voltage and output a reset signal; and a first reset signal line configured to transmit the reset signal to the plurality of first pixels.

### PRIORITY CLAIM AND CROSS REFERENCE TO RELATED APPLICATION

This patent document claims the priority and benefits of Korea Patent Application No. 10-2025-0053095, filed Apr. 23, 2025, the entire contents of which are incorporated herein by reference for all purposes.

### TECHNICAL FIELD

The disclosed technology relates to an image sensing device, and an imaging device including the same.

### BACKGROUND

With the development of information and communication technologies and the digitalization of image information, many electrical devices, such as digital cameras, camcorders, mobile phones, personal communication systems (PCSs), game machines, security cameras and medical micro-cameras, are now equipped with image sensors with improved performance. In general, an image sensor may include a pixel region that includes a photodiode and a circuit region. A pixel may include a photodiode and a transmission transistor. The transmission transistor may be disposed between the photodiode and a floating diffusion region and may transfer charges generated by the photodiode to the floating diffusion region.

### SUMMARY

The disclosed technology can be implemented in some embodiments to provide an image sensing device and an imaging device including the same that can reduce or remove reset noise or thermal noise (e.g., kTC noise) from the pixels even when a time gap exists between a reset period and a read-out period and.

In an embodiment, an image sensing device may include a plurality of first pixels configured to convert light into photocharge and arranged in a first row of a pixel array; a first feedback signal line coupled to the plurality of first pixels in the first row of the pixel array and configured to transmit a feedback signal from the plurality of first pixels; a first feedback amplifier coupled to the first feedback signal line to receive the feedback signal and configured to compare the feedback signal received from the first feedback signal line and a reference voltage to each other and output a reset signal; and a first reset signal line coupled to the plurality of first pixels in the first row of the pixel array and configured to transmit the reset signal to the plurality of first pixels.

In another embodiment, an image sensing device may include a plurality of first pixels configured to convert light into photocharge and disposed in a first row of a pixel array; a first feedback signal line coupled to the plurality of first pixels in the first row of the pixel array and configured to transmit a feedback signal from the plurality of first pixels; a first feedback amplifier coupled to the first feedback signal line to receive the feedback signal and configured to compare a feedback signal received from the first feedback signal line with a reference voltage and output a first reset signal; a first bandwidth control switch electrically connected to an output terminal of the first feedback amplifier; a first reset signal line coupled to the first bandwidth control switch and the first pixels, and configured to transmit the first reset signal from the first feedback amplifier to the plurality of first pixels; a plurality of second pixels configured to convert light into photocharge and disposed in a second row of the pixel array adjacent to the first row; a second feedback signal line coupled to the plurality of second pixels in the second row of the pixel array and configured to transmit a feedback signal from the second pixels; a second feedback amplifier coupled to the second feedback signal line to receive the feedback signal from the second pixels and configured to compare the feedback signal received from the second feedback signal line and a reference voltage to each other and output a second reset signal; a second bandwidth control switch electrically connected to an output terminal of the second feedback amplifier; a second reset signal line coupled to the second bandwidth control switch and the second pixels, and configured to transmit the second reset signal to the second pixels; and a column connection node configured to electrically couple the first bandwidth control switch to the second bandwidth control switch.

In another embodiment, an imaging device may include: an image sensing device configured to convert an optical signal into an electrical signal and generate image data; and an image signal processor (ISP) configured to process the image data, and the image sensing device may include: a plurality of first pixels configured to convert light into photocharge and arranged in a first row of a pixel array; a first feedback signal line configured to transmit a feedback signal from the plurality of first pixels; a first feedback amplifier configured to compare the feedback signal received from the first feedback signal line with a reference voltage and output a reset signal; and a first reset signal line configured to transmit the reset signal to the plurality of first pixels.

Other details of the embodiments are included in the detailed description and the accompanying drawings.

The image sensing device and the imaging device including the same according to the embodiments of the disclosed technology may reset a voltage of the floating diffusion region of all pixels in the same row to a reference voltage using a negative feedback system, and may remove the reset noise or kTC noise of the pixels by minimizing a voltage gap between the floating diffusion regions of the pixels.

The effects of the disclosed technology are not limited to the above-described effects and other effects which are not described herein may be clearly understood by those skilled in the art from the following description of the embodiments of the disclosed technology.

### BRIEF DESCRIPTION OF THE DRAWINGS

FIG. 1 is a block diagram illustrating an imaging system based on an embodiment.

FIG. 2 is a block diagram illustrating an image sensing device of an imaging system based on an embodiment.

FIG. 3 is a diagram illustrating a connection relationship of an image sensing device of an imaging system based on an embodiment.

FIG. 4 is a circuit diagram illustrating a row feedback structure of an imaging system based on an embodiment.

FIG. 5 is a waveform diagram illustrating examples of signals applied to a row feedback structure of FIG. 4.

FIG. 6 is a diagram illustrating a row feedback process according to a waveform diagram of FIG. 5.

FIG. 7 is a waveform diagram illustrating examples of signals applied to a row feedback structure of FIG. 4.

FIG. 8 is a diagram illustrating a row feedback process according to a waveform diagram of FIG. 7.

FIG. 9 is a circuit diagram illustrating a row feedback structure of an imaging system based on another embodiment.

FIG. 10 is a waveform diagram illustrating an example of signals applied to a row feedback structure of FIG. 9.

FIG. 11 is a diagram illustrating a row feedback process according to a waveform diagram of FIG. 10.

FIG. 12 is a waveform diagram illustrating examples of signals applied to a row feedback structure of FIG. 9.

FIG. 13 is a diagram illustrating a row feedback process according to a waveform diagram of FIG. 12.

### DETAILED DESCRIPTION

Hereinafter, various embodiments of the disclosed technology will be described with reference to the drawings.

It will be understood that when the terms “first” and “second” are used in some embodiments to identify and/or describe various components, these components should not be limited by these terms. The above terms are used to distinguish one component from another. For example, a first component may be referred to as a second component and vice versa.

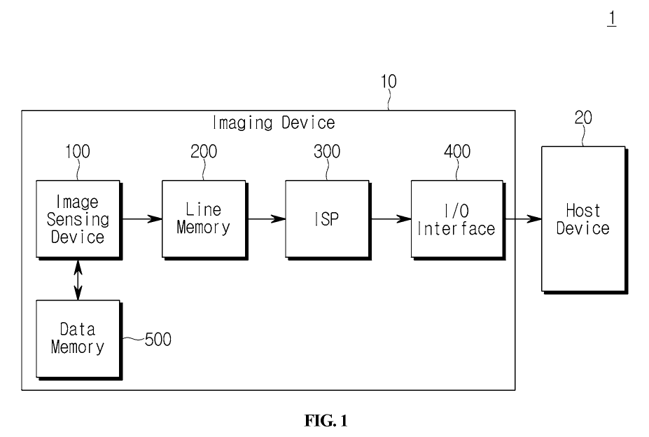

FIG. 1 is a block diagram illustrating an imaging system based on an embodiment.

Referring to FIG. 1, the imaging system 1 may include an imaging device 10 and a host device 20. Referring to FIG. 1, an imaging device 10 may refer to a device, for example, a digital still camera for photographing still images or a digital video camera for photographing moving images. For example, an imaging device 10 may be implemented as a Digital Single Lens Reflex (DSLR) camera, a mirrorless camera, or a smart phone, but is not limited thereto. The imaging device 10 may be a concept of including a device having a lens and an image pickup element such that the device can capture a target object and can thus create an image of the target object.

The imaging device 10 may include an image sensing unit 100, a signal line memory 200, an ISP (image signal processor) 300, an input/output (I/O) interface 400, and a data memory 500.

The image sensing device 100 may be a Complementary Metal Oxide Semiconductor Image Sensor (CIS) configured to convert an optical signal into an electric signal. The overall operations such as turning on/off, operation modes, operation timings, sensitivity, and the likes of the image sensing device 100 may be controlled by the ISP 300. The image sensing device 100 may transmit image data obtained by converting the optical signal into the electric signal to the signal line memory 200 according to the control of the ISP 300.

The line memory 200 may receive image data from the image sensing device 100, may store the received image data, and may transmit the stored image data to the ISP 300 according to the control of the ISP 300. The line memory 200 may include one or more volatile memory devices (e.g., DRAM, SRAM, etc.), one or more non-volatile memory devices (e.g., a flash memory), or a combination of the one or more volatile memory devices and the one or more non-volatile memory devices.

The ISP 300 may perform image signal processing on the image data stored in the line memory 200. The ISP 300 may reduce noise in the image data, and may perform various image signal processing operations such as gamma correction, color filter array interpolation, color matrix, color correction, color enhancement, lens distortion correction, etc. for image-quality improvement.

The I/O interface 400 may perform communication with the host device 20, and may transmit image data obtained through the image signal processing to the host device 20.

The host device 20 may be a processor configured to process the image data obtained through the image signal processing (e.g., by an application processor) and received from the imaging device 10. For example, the host device 20 may be an application processor, a memory configured to store image data (e.g., a non-volatile memory), or a display device configured to visually output image data (e.g., a liquid crystal display (LCD)).

The data memory 500 may store image data which is converted into a digital format by an analog-to-digital converter ADC.

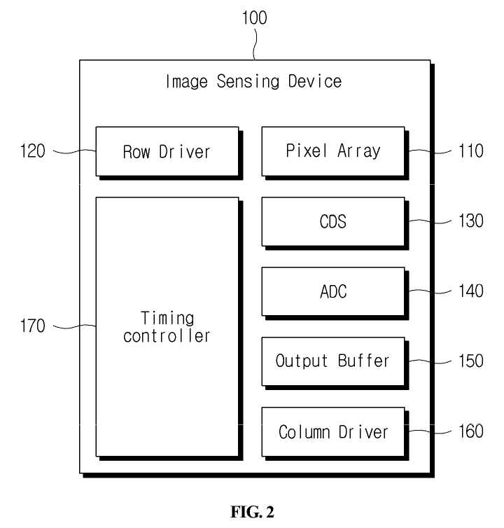

FIG. 2 is a block diagram illustrating an image sensing device of an imaging system based on an embodiment.

Referring to FIG. 2, the image sensing device 100 may include a pixel array 110, a row driver 120, a correlate double sampler (CDS) 130, and an analog-to-digital converter (ADC) 140, an output buffer 150, a column driver 160, and a timing controller 170. Here, each component of the image sensing device 100 is provided by way of example, and one or more components may be added or omitted as necessary.

The pixel array 110 may include a plurality of imaging pixels arranged in a plurality of rows and a plurality of columns. For example, the plurality of imaging pixels may be arranged in a two-dimensional pixel array including rows and columns. In another example, the plurality of imaging pixels may be arranged in a three-dimensional pixel array. The imaging pixels may convert an optical signal into an electrical signal on a unit pixel basis or a pixel group basis. The pixel array 110 may receive pixel control signals, including a row selection signal, a pixel reset signal and a transmission signal, from the row driver 120. Upon receiving the pixel control signals, corresponding pixels in the pixel array 110 may be activated to perform the operations corresponding to the row selection signal, the pixel reset signal, and the transmission signal. Each of the imaging pixels may generate photocharges corresponding to the intensity of incident light (or luminous intensity), may generate an electrical signal corresponding to the amount of photocharges, thereby sensing the incident light. Hereinafter, for convenience of description, the imaging pixel may also be referred to as a pixel.

The row driver 120 may activate the pixel array 110 to perform certain operations on the imaging pixels in the corresponding row based on commands and control signals provided by the timing controller 170.

The CDS 130 may sequentially sample and hold the reference signal and the image signal, which are provided to each of a plurality of column lines from the pixel array 110. That is, the CDS 130 may sample and hold levels of the reference signal and the image signal corresponding to each of the columns of the pixel array 110. The CDS 130 may receive a control signal from the timing controller 170, and may transfer the reference signal and the image signal of each of the columns as a correlated double sampling signal to the ADC 140.

The ADC 140 may convert the correlated double sampling signal output from the CDS 130 with respect to each column into digital signals, and output the image data. For example, the ADC 140 may receive the correlated double sampling signal for each of the columns from the CDS 130, convert it into digital signals, and output the digital signals.

The ADC 140 may include a plurality of column counters corresponding to columns of the pixel array 110, respectively. Each of the columns of the pixel array 110 may be electrically connected to each column counter, and the column counter may generate the image data by converting the correlated double sampling signal corresponding to each of the columns into a digital signal.

The output buffer 150 may temporarily hold the column-based image data provided from the ADC 140 and may output the image data. The output buffer 150 may temporarily store image data output from the ADC 140 based on the control signal of the timing controller 170.

The column driver 160 may select a column of the output buffer 150 based on a control signal from the timing controller 170, and may control the output buffer 150 to sequentially output the image data, which are temporarily stored in the selected column of the output buffer 150.

The timing controller 170 may control at least one among the row driver 120, the CDS 130, the ADC 254, the output buffer 150 and the column driver 160.

The timing controller 170 may provide at least one among the row driver 120, the CDS 130, the ADC 140, the output buffer 150 and the column driver 160 with a clock signal required for the operations of the respective components of the image sensing device 100, a control signal for timing control, and address signals for selecting a row or column. For example, the timing controller 170 may include a logic control circuit, a phase lock loop (PLL) circuit, a timing control circuit, and a communication interface circuit, etc.

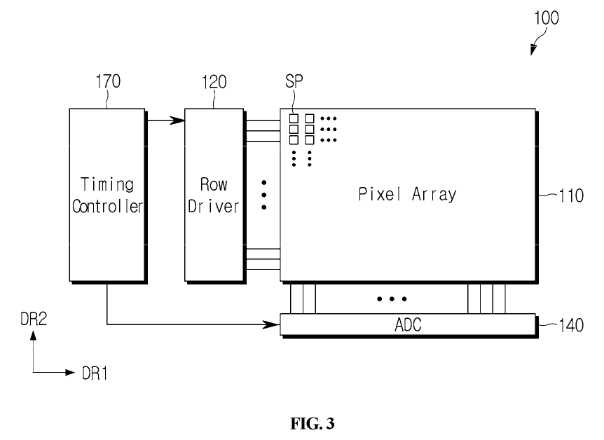

FIG. 3 is a diagram illustrating a connection relationship of the image sensing device of the imaging system based on an embodiment. Hereinafter, components which have been described in the above will be briefly described, or omitted.

Referring to FIG. 3, the pixel array 110 may include a plurality of pixels PX. The pixels PX may be arranged in a matrix form along a row direction and a column direction, however the arrangement of the pixels SP is not limited thereto. The pixels SP may include red, green, and blue pixels. However, the embodiments of the disclosed technology are not limited thereto, and the pixels SP may further include a white pixel or an infrared light pixel.

The pixel SP may include at least one photodetection region, and a circuit region overlapping the photodetection region. The photodetection region may include a photodetector, and the circuit region may include a pixel circuit electrically connected to the photodetector.

The plurality of pixels SP may be electrically connected to the row driver 120 through a row signal line extending in a first direction DR1. The row signal line may include a row enable line, a bandwidth control line, and a selection signal line, but is not limited thereto.

The plurality of pixels SP may be electrically connected to the ADC 140 through a column signal line extending in a second direction DR2. The column signal line may include an output line, but is not limited thereto. The ADC 140 may include a column counter corresponding to the pixels SP arranged in the same column.

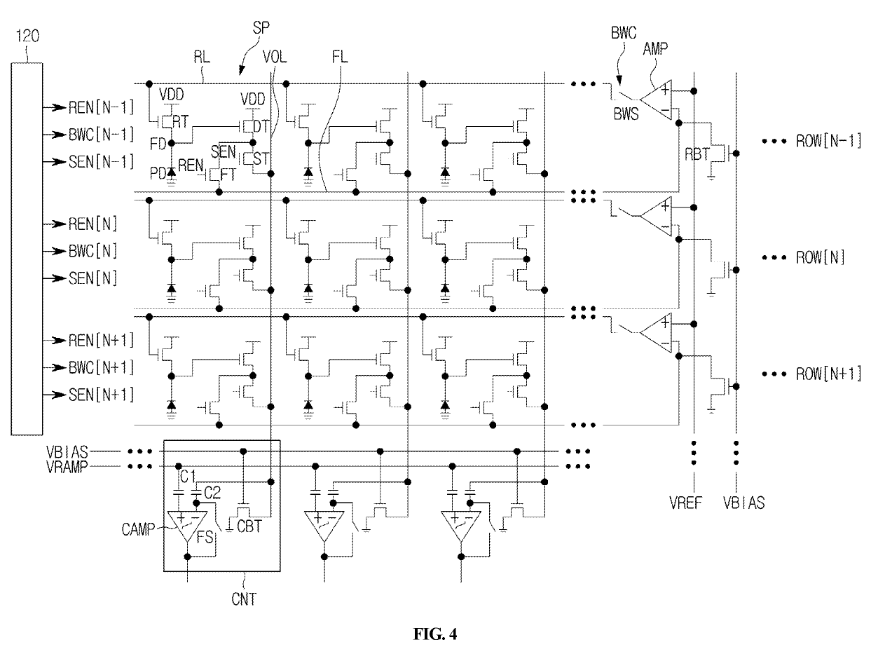

FIG. 4 is a circuit diagram illustrating a row feedback structure of the imaging system based on an embodiment.

Referring to FIG. 4, the plurality of pixels SP may be arranged in a matric array including a plurality of rows and a plurality of columns. For example, the plurality of pixels SP may be arranged along an (N-1)th row ROW[N-1] (N is a positive integer), an Nth row ROW[N], and an (N+1)th row ROW[N+1]. A plurality of pixels SP arranged in the same row may correspond to one feedback amplifier AMP by coupling each pixel SP in that row to the one corresponding feedback amplifier AMP and different feedback amplifiers AMP respectively corresponding to different rows of pixels SP are provided as illustrated in FIG. 4. The pixels SP arranged in the same row may be coupled to two common signal lines for the different pixels SP in that same row: a feedback signal line FL illustrated in the lower side of the row of pixels SP and a reset signal line RL illustrated in the upper side of the row of pixels SP. The pixels SP arranged in the same row may be electrically connected to the row’s corresponding feedback amplifier AMP through at least one switch, which is shown as a bandwidth switch (BWS) connected to the output terminal of the corresponding feedback amplifier AMP and the corresponding reset signal line RL for that row in FIG. 4. As explained below, such a configuration of the row of pixels SP with the feedback amplifier AMP, the feedback amplifier AMP, and the feedback signal line FL and the reset signal line RL effectuate and form a negative feedback loop for each row of pixels SP that includes the row’s feedback signal line FL, the row’s feedback amplifier AMP, the row’s reset signal line RL and the row’s bandwidth switch (BWS).

The row driver 120 may activate the pixels SP included in the same row in response to the commands and the control signals provided by the timing controller 170. The row driver 120 may apply a row enable signal REN[N-1], a bandwidth control signal BWC[N-1], and a selection signal SEN[N-1] to the pixels SP of the (N-1)th row ROW[N-1]. The row driver 120 may apply a row enable signal REN[N], a bandwidth control signal BWC[N], and a selection signal SEN[N] to the pixels SP of the Nth row ROW[N]. The row driver 120 may apply a row enable signal REN[N+1], a bandwidth control signal BWC[N+1], and a selection signal SEN[N+1] to the pixels SP of the (N+1)th row ROW[N+1].

Each pixel SP may include a photodetector PD for sensing the received incident light at that pixel SP, a floating diffusion region FD coupled to the photodetector PD to accumulate photocharge from the photodetector PD and the associated pixel circuitry which includes a reset transistor RT for resetting the pixel SP after a readout operation, a driver transistor DT for reading out the photocharge, a selection transistor ST for selecting that particular pixel SP for readout, and a feedback transistor FT coupled to the feedback signal line FL for implementing the technology disclosed in this patent document.

The photodetector PD with the pixel SP may generate and accumulate photocharge corresponding to an intensity of the incident light. For example, the photodetector PD may be implemented using a photo diode, a photo transistor, a photo gate, a pinned type photo diode or a combination thereof. When the photodetector PD is implemented using a photo diode, it may include a region doped with impurities of a second conductivity type (e.g., an n-type) in a substrate having a first conductivity type (e.g., a p-type). The photodetector PD may be a photodetector for detecting a phase. A first electrode of the photodetector PD may be electrically connected to the ground, and a second electrode thereof may be electrically connected to the floating diffusion region FD.

The floating diffusion region FD within the pixel SP may accumulate photocharges delivered from the photodetector PD. For example, the floating diffusion region FD may be a region doped with impurities having the second conductivity type (for example, n-type) in the substrate having the first conductivity type (for example, p-type), and the substrate and the impurity-doped region may be modeled to a junction capacitor. The floating diffusion region FD may be electrically connected to the second electrode of the photodetector PD, a source electrode of the reset transistor RT for resetting the charge level in the floating diffusion region FD, and a gate electrode of the driver transistor DT. The floating diffusion region FD may include a floating diffusion electrode (not illustrated).

The reset transistor RT with the pixel SP may be electrically connected between a power supply voltage supply node VDD and the floating diffusion region FD. The reset transistor RT may reset the voltage of the floating diffusion region FD to a power supply voltage VDD based on a voltage of the reset signal line RL which is connected to the gates of the reset transistors RT of the pixels SP on the same row. The reset signal line RL may supply a reset voltage to a gate electrode of the reset transistor RT of each of the pixels SP arranged in the same row. The gate electrode of the reset transistor RT may receive the reset voltage from the reset signal line RL, a drain electrode of the reset transistor RT may receive the power supply voltage VDD, and the source electrode of the reset transistor RT may be electrically connected to the floating diffusion region FD.

The driver transistor DT within the pixel SP may be connected between the power supply voltage VDD and the selection transistor ST, and may amplify a change of an electric potential in the floating diffusion region FD and may deliver the amplified potential change to the selection transistor ST. The driver transistor DT may operate as a source follower. The driver transistor DT may be connected between the power supply voltage VDD and the feedback transistor FT, and may sample a reset voltage of the floating diffusion region FD and deliver it to the feedback transistor FT. A gate electrode of the driver transistor DT may be electrically connected to the floating diffusion region FD, a drain electrode of the driver transistor DT may receive the power supply voltage VDD, and a source electrode of the driver transistor DT may be electrically connected to a drain electrode of the selection transistor ST and a drain electrode of the feedback transistor FT.

The selection transistor ST within pixel SP may be electrically connected between the driver transistor DT and an output signal line VOL that is shared by the different pixels SP in a common column but in different rows. The selection transistor ST may receive an electric signal from the driver transistor DT, and may supply an output voltage to the output signal line VOL in response to a selection signal SEN. The pixels SP arranged in the same column but in different rows may be electrically connected to the same output signal line VOL. A gate electrode of the selection transistor ST may receive the selection signal SEN, a drain electrode of the selection transistor ST may be electrically connected to the source electrode of the driver transistor DT, and a source electrode of the selection transistor ST may be electrically connected to the output signal line VOL to transmit the output of the driver transistor DT to the output signal line VOL via the selection transistor ST is turned on.

The feedback transistor FT may be connected between the driver transistor DT and the row’s corresponding feedback signal line FL. The feedback transistor FT may receive an electric signal from the driver transistor DT, and may deliver a feedback voltage to the feedback signal line FL based on the row enable signal REN applied to its gate to turn on the feedback transistor FT to allow the feedback voltage to reach the feedback signal line FL or to turn off the feedback transistor FT to block the feedback voltage from reaching the feedback signal line FL. The pixels SP arranged in the same row may be electrically connected to the same feedback signal line FL. In the illustrated example in FIG. 4, the gate electrode of the feedback transistor FT may receive the row enable signal REN, the drain electrode of the feedback transistor FT may be electrically connected to the source electrode of the driver transistor DT, and the source electrode of the feedback transistor FT may be electrically connected to the feedback signal line FL.

The feedback amplifier AMP coupled on the reset signal line RL via the bandwidth switch BWS between the row of pixels SP and the feedback amplifier AMP may form a negative feedback system for the pixels SP arranged in a corresponding row. The feedback amplifier AMP may compare a feedback voltage received from the feedback signal line FL with a reference voltage VREF, and supply the reset voltage to the reset signal line RL based on the comparison. In an implementation, the feedback amplifier AMP may include an operational amplifier with differential inputs (inverting (−) and non-inverting (+)). The feedback amplifier AMP may implement a negative feedback mechanism, and may reset the voltage of the floating diffusion region FD of the pixels SP arranged in the same row, to the reference voltage VREF. A first input terminal (e.g., non-inverting input (+)) of the feedback amplifier AMP may receive the reference voltage VREF, and a second input terminal (e.g., inverting input (-)) thereof may receive the feedback voltage from the feedback signal line FL. The feedback signal line FL may carry a feedback signal representing the highest voltage of the floating diffusion region FD among the pixels SP. The feedback amplifier AMP may reset the voltage of the floating diffusion region FD via sending out its output to the reset signal line RL coupled to the reset resistors of the pixels SP on the same row by iteratively performing a feedback process multiple times. In each iteration, the pixel SP with the highest floating diffusion region (FD) voltage may vary (e.g., FD voltage refers to a voltage of the floating diffusion region FD). For example, a first pixel may have the highest FD voltage in a first feedback process, and a second pixel may have the highest FD voltage in a second feedback process. As the feedback process continues, the FD voltages of the pixels SP may gradually approach the reference voltage VREF, and may eventually converge to the reference voltage VREF. As a result, the image sensing device 100 may effectively remove or reduce the reset noise or thermal noise (e.g., kTC noise) of the pixels SP, and improve the reliability of the imaging device 100 by improving its photodetection sensitivity.

An output terminal of the feedback amplifier AMP may be electrically connected to the reset signal line RL through a bandwidth control switch BWS. The bandwidth control switch BWS may be turned on based on the bandwidth control signal BWC.

A row bias transistor RBT may electrically connect the feedback signal line FL to the ground in response to a bias voltage VBIAS. The row bias transistor RBT may induce the feedback voltage on the feedback signal line FL to be applied to the second input terminal (-) of the of the feedback amplifier AMP. The pixels arranged in the same row may be electrically connected to a single row bias transistor RBT through the feedback signal line FL.

The example of the sensor circuit design in FIG. 4 may also provide a column counter CNT for different pixels in the same column of the pixel array but in different rows to convert the output voltage of the pixels SP arranged in the corresponding column into a digital signal. The column counter CNT may include a column amplifier CAMP, a first capacitor C1, a second capacitor C2, a feedback switch FS, and a column bias transistor CBT.

A digital signal may be generated by comparing the change in a ramp voltage VRAMP of the column amplifier CAMP with a change amount of the output voltage of the pixel SP to each other. A first electrode of the first capacitor C1 may receive the ramp voltage VRAMP, and a second electrode thereof may be electrically connected to a first input terminal (+) of the column amplifier CAMP. In some implementations, the ramp voltage VRAMP may correspond to a sawtooth waveform. The first capacitor C1 may maintain a potential difference (voltage difference) between the ramp voltage VRAMP and the first input terminal (+) of the column amplifier CAMP. A first electrode of the second capacitor C2 may be electrically connected to the output signal line VOL, and a second electrode of the second capacitor C2 may be electrically connected to a second input terminal (-) of the column amplifier CAMP. The second capacitor C2 may maintain a potential difference between the output signal line VOL and the second input terminal (-) of the column amplifier CAMP. The feedback switch FS may establish the negative feedback by electrically connecting the output terminal of the column amplifier CAMP to its second input terminal (-). Therefore, the column amplifier CAMP may generate digital image data by counting a magnitude of the output voltage based on the ramp voltage VRAMP.

The column bias transistor CBT may electrically connect the output signal line VOL to the ground based on the bias voltage VBIAS. The column bias transistor CBT may induce the output voltage of the output signal line VOL to the second capacitor C2 electrically connected to the second input terminal (-) of the column amplifier CAMP. The pixels SP arranged in the same column may be electrically connected to one column bias transistor CBT through the output signal line VOL.

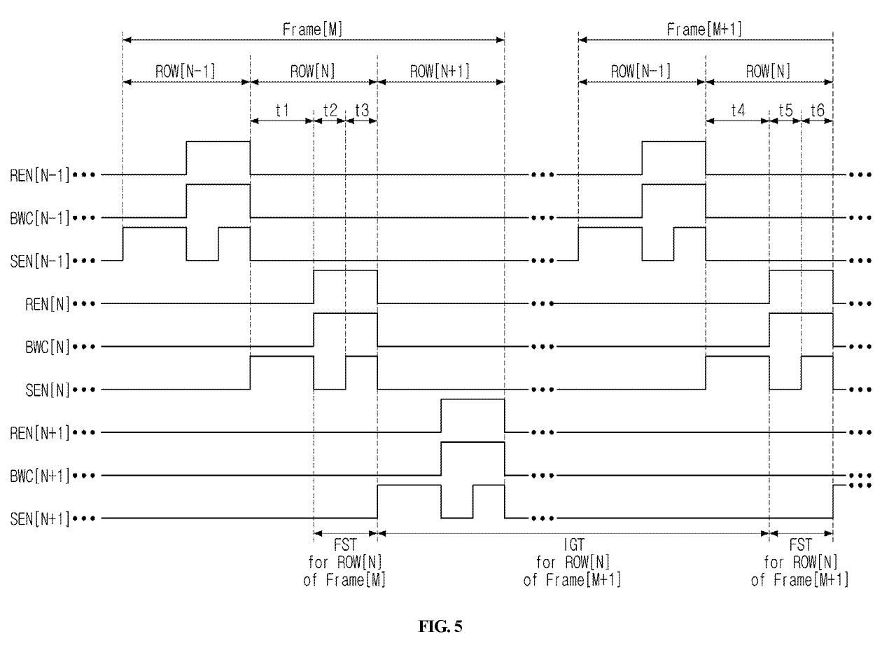

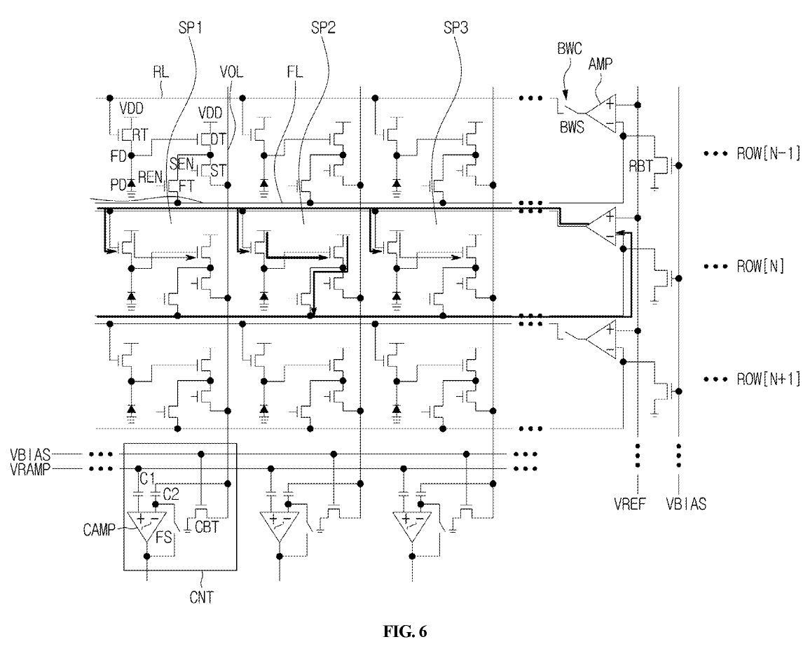

FIG. 5 is a waveform diagram illustrating examples of signals applied to the row feedback structure of FIGS. 4, and FIG. 6 is a diagram illustrating the row feedback process according to the waveform diagram of FIG. 5.

Referring to FIGS. 5 and 6, the pixels SP may sequentially detect light on a row-by-row basis. After the pixels SP of the (N-1)th row ROW[N-1] detects light, the pixels SP of the Nth row ROW[N] may detect light. After the pixels SP of the Nth row ROW[N] detects light, the pixels SP of the (N+1)th row ROW[N+1] may detect light. After all pixels SP in all rows have detected light during an Mth frame Frame[M], all pixels SP in all rows may detect light in an M+1th frame Frame[M+1]. The first to third periods t1, t2, and t3 are sequentially performed during the Mth frame Frame[M], and the fourth to sixth periods t4, t5, and t6 may be sequentially performed during the (M+1)th frame Frame[M+1].

The selection transistor ST of each of the pixels of the Nth row ROW[N] may receive a high-level selection signal SEN[N] during the first and third periods t1 and t3. The selection transistor ST may be turned on during the first period t1 to perform readout and sample the output voltage. The selection transistor ST may be turned on during the third period t3, and sample the reset voltage of the floating diffusion region FD.

The feedback transistor FT of each of the pixels of the Nth row ROW[N] may receive a high-level row enable signal REN[N] during the second and third periods t2 and t3. The feedback transistor FT may be turned on during the second and third periods t2 and t3, and transmit the feedback voltage to the feedback signal line FL. The pixels arranged in the same row may be electrically connected to the same feedback signal line FL. The feedback signal line FL may carry the feedback signal that represents the highest voltage of the floating diffusion region FD among the pixels SP of the Nth row ROW[N].

The bandwidth control switch BWS of the Nth row ROW[N] may receive a high-level bandwidth control signal WBC[N] during the second and third periods t2 and t3. The bandwidth control switch BWS may be turned on during the second and third periods t2 and t3, and deliver the output of the feedback amplifier AMP to the reset signal line RL. In the feedback process, the feedback amplifier AMP may supply the reset voltage to the reset signal line RL.

Referring to FIG. 6, the feedback amplifier AMP may reset the voltage of the floating diffusion region FD of the pixels SP by iteratively performing the feedback process multiple times. The pixel SP having the highest voltage of the floating diffusion region FD may be changed each time in the feedback process. The pixels SP of the Nth row ROW[N] may include first to third pixels SP1, SP2, and SP3. For example, in a first feedback process illustrated in FIG. 6, when the amount of the photocharge accumulated in the floating diffusion region FD of the second pixel SP2 is high (e.g., the highest), a gate-source voltage Vgs of the reset transistor RT of the second pixel SP2 may be high (e.g., the highest), and a drain-source current I_{ds} flowing in the reset transistor RT of the second pixel SP2 may be high (e.g., the highest). Accordingly, the second pixel SP2 may have a high or the highest voltage of the floating diffusion region FD, and the voltage of the floating diffusion region FD of the second pixel SP2 may get close to the reference voltage VREF first. The feedback signal line FL may carry the feedback signal representing the voltage of the floating diffusion region FD of the second pixel SP2 to the second input terminal (-) of the feedback amplifier AMP. The feedback amplifier AMP may supply the reset voltage to the reset signal line RL by comparing the feedback voltage received from the feedback signal line FL and the reference voltage VREF to each other, and a second feedback process may be performed.

For example, in the second feedback process (not illustrated), a gate-source voltage Vgs of the reset transistor RT of the first pixel SP1 may be the highest among the pixels, resulting in the largest drain-source current Ids flowing in the reset transistor RT of the first pixel SP1. In this case, the floating diffusion region FD of the first pixel SP1 may have the highest voltage, which then approaches the reference voltage VREF. The feedback signal line FL may carry the voltage of the floating diffusion region FD of the first pixel SP1 representing the second input terminal (-) of the feedback amplifier AMP. The feedback amplifier AMP may supply the reset voltage to the reset signal line RL by comparing the feedback voltage received from the feedback signal line FL with the reference voltage VREF, and subsequently a third feedback process may be performed.

The feedback process may be repeated multiple times in the above-described manner, and consequently, the voltage of the floating diffusion region FD of the pixels SP in the Nth row ROW[N] may reach the reference voltage VREF.

The pixel SP may not include an additional transmission transistor between the photodetector PD and the floating diffusion region FD. The pixel SP may not separate the read-out period from the photocharge accumulation period of the photodetector PD, and instead both the read-out period and the photocharge accumulation period may be performed within the same phase. For example, the pixels SP in the Nth row ROW[N] during the Mth frame Frame[M] may have a feedback reset period FST during the second and third periods t2 and t3. The pixels SP of the Nth row ROW[N] of the (M+1)th frame Frame[M+1] may have a photocharge accumulation period starting from the end of the third period t3 and lasting until the end of the fourth period t4. The pixels SP of the Nth row ROW[N] of the (M+1)th frame Frame[M+1] may perform the readout during the fourth period t4 to sample the output voltage. Therefore, a time gap may exist between the feedback reset period FST and the readout period. The pixels SP of the Nth row ROW[N] of the (M+1)th frame Frame[M+1] may have the feedback reset period FST during the fifth and sixth periods t5 and t6.

As the image sensing device 100 forms a negative feedback loop that includes the pixels SP arranged in the same row, the feedback signal line FL, the feedback amplifier AMP, and the reset signal line RL, the image sensing device 100 may reset the voltage of the floating diffusion region FD of all pixels SP in the same row to the reference voltage VREF. This configuration may minimize voltage variation among the floating diffusion regions FD of the pixels SP. In this way, the image sensing device 100 may remove or reduce the reset noise or the kTC noise of the pixels SP, and improve photodetection sensitivity, thereby improving the overall reliability of the imaging device 10.

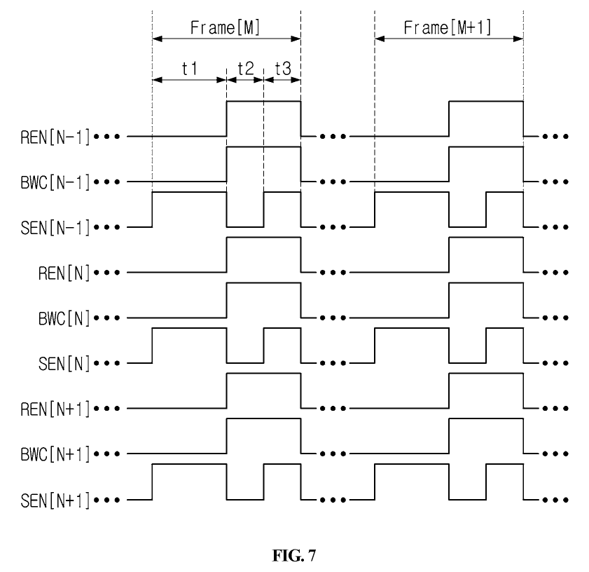

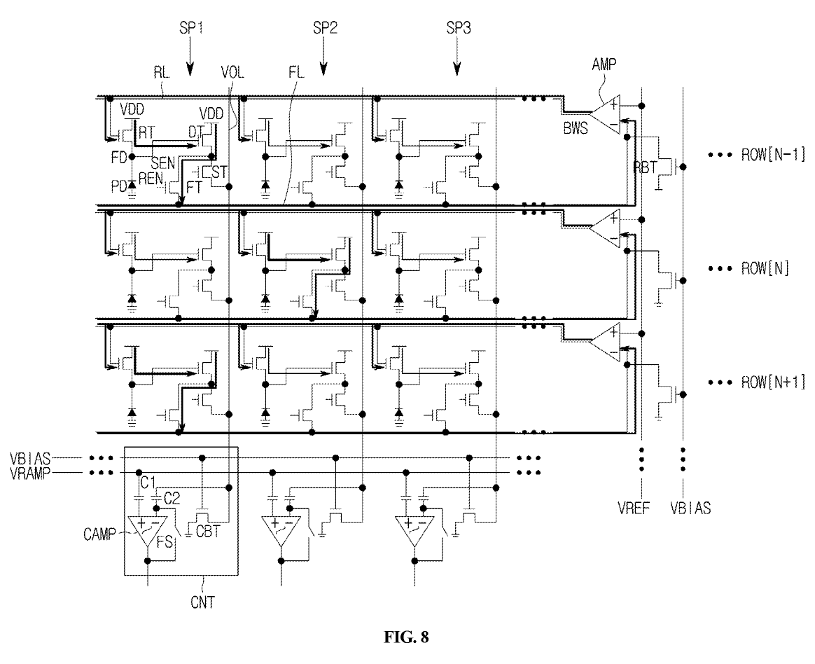

FIG. 7 is a waveform diagram illustrating examples of signals applied to a row feedback structure of FIG. 4, and FIG. 8 is a diagram illustrating a row feedback process according to a waveform diagram of FIG. 7. Hereinafter, components which have been described in the above will be briefly described, or omitted.

Referring to FIGS. 7 and 8, the pixels SP may perform the feedback process in all the rows simultaneously. For example, the pixels SP of the (N-1)th row ROW[N-1], the pixels SP of the Nth row ROW[N], and the pixels SP of the (N+1)th row ROW[N+1] may perform the feedback process by supplying the reset signal simultaneously.

The selection transistor ST of each of the pixels SP of the (N-1)th row ROW[N-1] may receive a high-level selection signal SEN[N-1] during the first and third periods t1 and t3. The selection transistor ST of each of the pixels SP of the Nth row ROW[N] may receive a high-level selection signal SEN[N] during the first and third periods t1 and t3. The selection transistor ST of each of the pixels SP of the (N+1)th row ROW[N+1] may receive a high-level selection signal SEN[N+1] during the first and third periods t1 and t3.

The feedback transistor FT of each of the pixels SP of the (N-1)th row ROW[N-1] may receive a high-level row enable signal SEN[N-1] during the second and third periods t2 and t3. The feedback transistor FT of each of the pixels SP of the Nth row ROW[N] may receive a high-level row enable signal SEN[N] during the second and third periods t2 and t3. The feedback transistor FT of each of the pixels SP of the (N+1)th row ROW[N+1] may receive a high-level row enable signal SEN[N+1] during the second and third periods t2 and t3.

The bandwidth control switch BWS of each of the pixels SP of the (N-1)th row ROW[N-1] may receive a high-level bandwidth control signal BWC[N-1] during the second and third periods t2 and t3. The bandwidth control switch BWS of each of the pixels SP of the Nth row ROW[N] may receive a high-level bandwidth control signal BWC[N] during the second and third periods t2 and t3. The bandwidth control switch BWS of each of the pixels SP of the (N+1)th row ROW[N+1] may receive a high-level bandwidth control signal BWC[N+1] during the second and third periods t2 and t3.

Referring to FIG. 8, the feedback amplifier AMP of each of the N-1th row ROW[N-1], the Nth row ROW[N], and the N+1th row ROW[N+1] may reset the voltage of the floating diffusion region FD of the pixels SP by iteratively performing the feedback process multiple times. In each iteration, the pixel SP with the highest floating diffusion region (FD) voltage may vary (e.g., FD voltage refers to a voltage of the floating diffusion region FD). The pixels SP of each of the (N-1)th row ROW[N-1], the Nth row ROW[N], and the (N+1)th row ROW[N+1] may include first to third pixels SP1, SP2, and SP3. The order in which the pixels SP of each of the (N-1)th row ROW[N-1], the Nth row ROW[N], and the (N+1)th row ROW[N+1] are reset may be different from each other.

For example, in the first feedback process in FIG. 8, the first pixel SP1 of the (N-1)th row ROW[N-1] may have the highest FD voltage, and the FD voltage of the first pixel SP1 may approach the reference voltage VREF first. The feedback signal line FL of the (N-1)th row ROW[N-1] may carry the feedback signal representing the voltage of the floating diffusion region FD of the first pixel SP1 to the second input terminal (-) of the feedback amplifier AMP.

In addition, during the first feedback process, the second pixel SP2 of the Nth row ROW[N] may have the highest FD voltage, and the voltage of the floating diffusion region FD of the second pixel SP2 approach the reference voltage VREF first. The feedback signal line FL of the Nth row ROW[N] may carry the feedback signal representing the voltage of the floating diffusion region FD of the second pixel SP2 to the second input terminal (-) of the feedback amplifier AMP.

In addition, during the first feedback process, the first pixel SP1 of the (N+1)th row ROW[N+1] may have the highest voltage of the floating diffusion region FD, and the voltage of the floating diffusion region FD of the first pixel SP1 may get close to the reference voltage VREF first. The feedback signal line FL of the (N+1)th row ROW[N+1] may carry the feedback signal representing the voltage of the floating diffusion region FD of the first pixel SP1 to the second input terminal (-) of the feedback amplifier AMP.

The feedback process may be repeated multiple times in the above-described manner, and consequently, the voltage of the floating diffusion region FD of the pixels SP of the N-1th row ROW[N-1], the Nth row ROW[N], and the N+1th row ROW[N+1] may reach the reference voltage VREF simultaneously. Therefore, the image sensing device 100 may remove the reset noise or the kTC noise of the pixels SP, and improve photodetection sensitivity, thereby improving reliability of the imaging device 10.

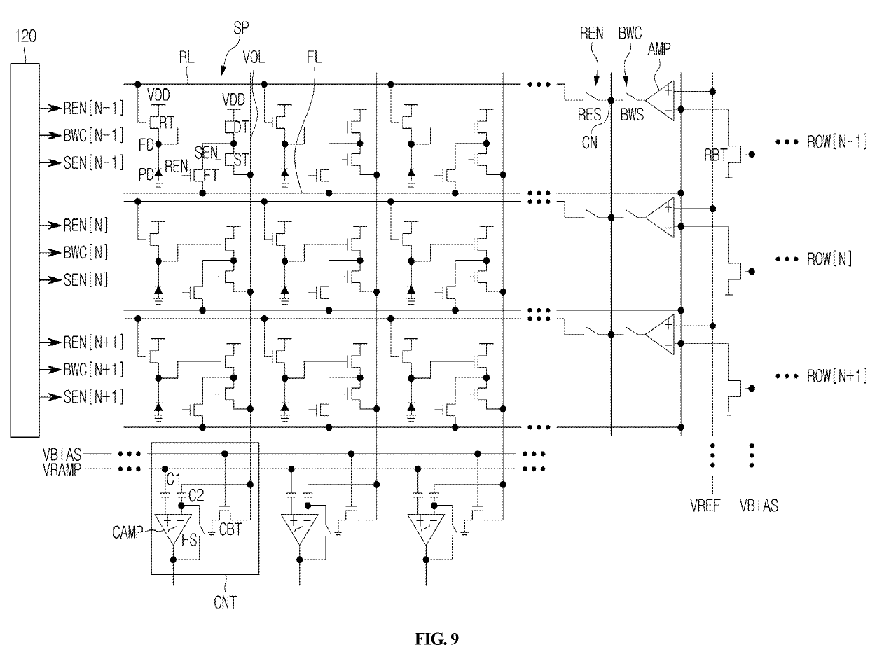

FIG. 9 is a circuit diagram illustrating a row feedback structure of an imaging system based on another embodiment. The row feedback structure in FIG. 9 is a structure in which the row feedback structure illustrated in FIG. 4 further includes a column connection node CN and a reset enable switch RES, and components that have been described in the above will be briefly described, or omitted.

Referring to FIG. 9, although the pixels arranged in the same row may correspond to the feedback amplifier AMP of the corresponding row, they may be electrically connected to the feedback amplifier AMP of a different row through the column connection node CN. The pixels arranged in the same row may form a negative feedback loop that includes the feedback signal line FL, the feedback amplifier AMP, and the reset signal line RL.

The pixel SP may include a photodetector PD, a reset transistor RT, a driver transistor DT, a selection transistor ST, and a feedback transistor FT. The configuration of the photodetector PD, the reset transistor RT, the driver transistor DT, the selection transistor ST, and the feedback transistor FT of the pixel SP is the same as that disclosed in FIG. 4, therefore, the description thereof will be omitted.

A plurality of feedback amplifiers AMP may be arranged in a one-to-one correspondence with the plurality of rows. The feedback amplifiers AMP assigned to each of the plurality of rows may be electrically connected to each other through the column connection node CN. Each of the feedback amplifiers AMP may form a negative feedback system for the pixels SP arranged in its corresponding row. The feedback amplifier AMP may compare a feedback voltage received from the feedback signal line with the reference voltage VREF, and supply the reset voltage to the reset signal line RL based on the comparison. The feedback amplifier AMP may implement a negative feedback mechanism to reset the floating diffusion region FD of the pixels SP arranged in (belonging to) the same row, to the reference voltage VREF. A first input terminal (e.g., non-inverting input (+)) of the feedback amplifiers AMP electrically connected to each other may receive the reference voltage VREF, and a second input terminal (e.g., inverting input (-)) thereof electrically connected to each other may be electrically connected to a plurality of feedback signal lines FL. The second input terminal (-) of the feedback amplifiers AMP may receive a feedback voltage from one of the plurality of feedback signal lines FL. The feedback signal line FL may carry the feedback signal representing the highest FD voltage (e.g., FD voltage refers to a voltage of the floating diffusion region FD) among the pixels SP. The feedback amplifier AMP may reset the voltage of the floating diffusion region FD by iteratively performing the feedback process multiple times. As the feedback process continues, the voltage of the floating diffusion region FD of the pixels SP may gradually approach the reference voltage VREF, and may eventually converge to the reference voltage VREF. The image sensing device 100 may achieve a sufficient amplifier gain by performing the feedback process through a plurality of feedback amplifiers AMP, even when a large number of pixels SP are arranged in a single row. This configuration may prevent degradation of the negative feedback effect caused by the bandwidth limitation due to amplifier shortages. Therefore, the image sensing device 100 may effectively remove or reduce the reset noise or kTC noise of the pixels SP, thereby improving the photodetection sensitivity and overall reliability of the imaging device 100 and.

The output terminal of the feedback amplifier AMP may be electrically connected to the reset signal line RL through the bandwidth control switch BWS. The bandwidth control switch BWS may be turned on based on the bandwidth control signal BWC. The bandwidth control switch BWS arranged in each of the plurality of rows may be turned on simultaneously, and the output terminal of the feedback amplifier AMP may be electrically connected to each other through the column connection node CN.

A plurality of reset enable switches RES may be arranged in a one-to-one correspondence with the plurality of feedback amplifiers AMP. The reset enable switches RES may be turned on based on the row enable signal REN. The reset enable switch RES may electrically connect the column connection node CN to the reset signal line RL of a certain row. Therefore, the reset enable switch RES may select a row for forming the negative feedback loop among the plurality of rows.

The column counter CNT may convert the output voltage of the pixels SP arranged in the corresponding column into a digital signal. The column counter CNT may include a column amplifier CAMP, a first capacitor C1, a second capacitor C2, a feedback switch FS, and a column bias transistor CBT. The configuration of the column amplifier CAMP, the first capacitor C1, the second capacitor C2, the feedback switch FS, and the column bias transistor CBT of the column counter CNT is the same as that disclosed in FIG. 4, and thus, a detailed description thereof will be omitted.

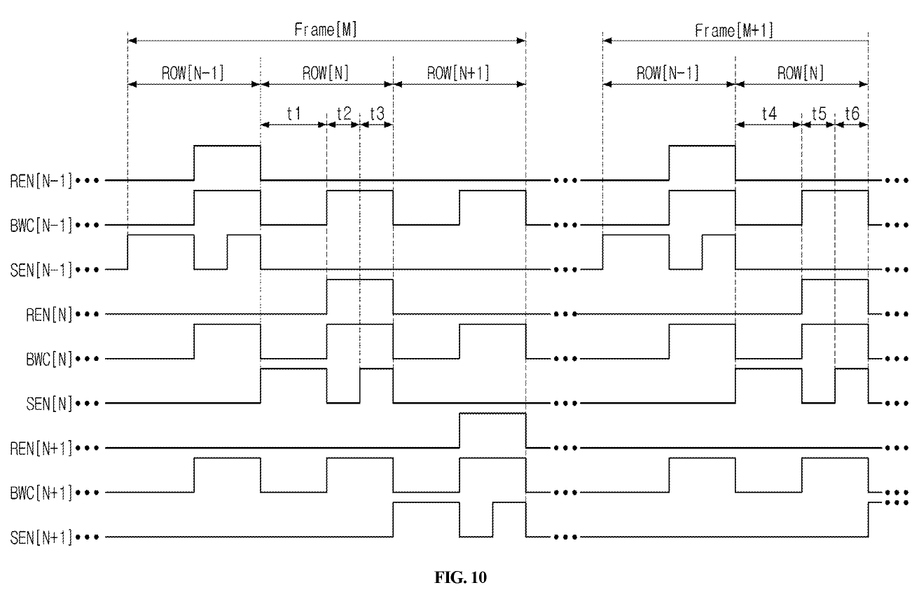

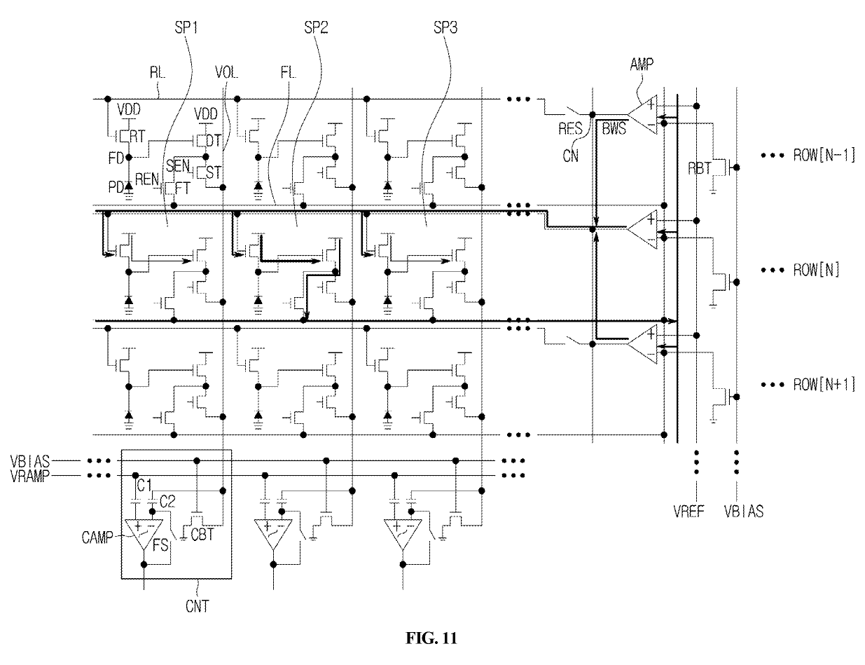

FIG. 10 is a waveform diagram illustrating examples of signals applied to the row feedback structure of FIG. 9, and FIG. 11 is a diagram illustrating a row feedback process according to a waveform diagram of FIG. 10.

Referring to FIGS. 10 and 11, the pixels SP may sequentially detect light on a row-by-row basis. The pixels SP of each of the (N-1)th row ROW[N-1], the Nth row ROW[N], and the (N+1)th row ROW[N+1] may detect light sequentially. After the pixels SP in all rows detect light during the Mth frame Frame[M], the pixels SP in all rows may detect light during the (M+1)th frame Frame[M+1].

The selection transistor ST of each of the pixels SP of the Nth row ROW[N] may receive a high-level selection signal SEN[N] during the first and third periods t1 and t3. The selection transistor ST may be turned on during the first period t1 to perform readout and sample the output voltage. The selection transistor ST may be turned on during the third period t3, and sample the reset voltage of the floating diffusion region FD.

The feedback transistor FT of each of the pixels of the Nth row ROW[N] may receive a high-level row enable signal REN[N] during the second and third periods t2 and t3. The feedback transistor FT may be turned on during the second and third periods t2 and t3, and deliver the feedback voltage to the feedback signal line FL. The pixels arranged in the same row may be electrically connected to the same feedback signal line FL. The feedback signal line FL may carry the feedback signal representing the highest voltage of the floating diffusion region FD among the pixels SP of the Nth row ROW[N].

The bandwidth control switches BWS arranged in the plurality of rows may be turned on simultaneously. For example, the bandwidth control switch BWS of each of the pixels SP of the N-1th row ROW[N-1], the Nth row ROW[N], and the N+1th row ROW[N+1] may receive a high-level bandwidth control signal BWC[N-1], BWC[N], and BWC[N+1] during the second and third periods t2 and t3. The bandwidth control switches BWS may be turned on during the second and third periods t2 and t3 and may deliver the output of the feedback amplifiers AMP to the column connection node CN.

The reset enable switch RES of the Nth row ROW[N] may be turned on based on the row enable signal REN[N]. The reset enable switch RES may electrically connect the column connection node CN to the reset signal line RL of the Nth row ROW[N]. Therefore, the reset enable switch RES may select the Nth row ROW[N] among the plurality of rows and may form the negative feedback loop. The output of the feedback amplifiers AMP may be transmitted to the reset signal line RL through the column connection node CN and the reset enable switch RES.

Referring to FIG. 11, the feedback amplifiers AMP may reset the voltage of the floating diffusion region FD of the pixels SP by iteratively performing the feedback process multiple times. The pixel SP having the highest FD voltage may be changed at each feedback process iteration. The pixels SP of the Nth row ROW[N] may include first to third pixels SP1, SP2, and SP3. For example, during a first feedback process illustrated in FIG. 11, the second pixel SP2 may have the highest FD voltage, and the voltage of the floating diffusion region FD of the second pixel SP2 may approach the reference voltage VREF first. The feedback signal line FL may carry the feedback signal representing the voltage of the floating diffusion region FD of the second pixel SP2 to the second input terminal (-) of the feedback amplifier AMP arranged in the plurality of rows. The feedback amplifiers AMP may supply the reset voltage to the reset signal line RL by comparing the feedback voltage received from the feedback signal line FL with the reference voltage VREF, and subsequently a second feedback process may be performed.

The feedback process may be repeated multiple times in the above-described manner, and consequently, the voltage of the floating diffusion region FD of the pixels SP of the Nth row ROW[N] may reach the reference voltage VREF.

The image sensing device 100 may achieve a sufficient amplifier gain by performing the feedback process through a plurality of feedback amplifiers AMP, even when a large number of pixels SP are arranged in a single row. This configuration may prevent degradation of the negative feedback effect caused by the bandwidth limitation due to amplifier shortages. The image sensing device 100 may reset the voltage of the floating diffusion region FD of all pixels SP to the reference voltage VREF, and may minimize the voltage variation among the floating diffusion regions FD of the pixels SP. Therefore, the image sensing device 100 may effectively remove or reduce the reset noise or kTC noise of the pixels SP, thereby improving the photodetection sensitivity and the overall reliability of the imaging device 100.

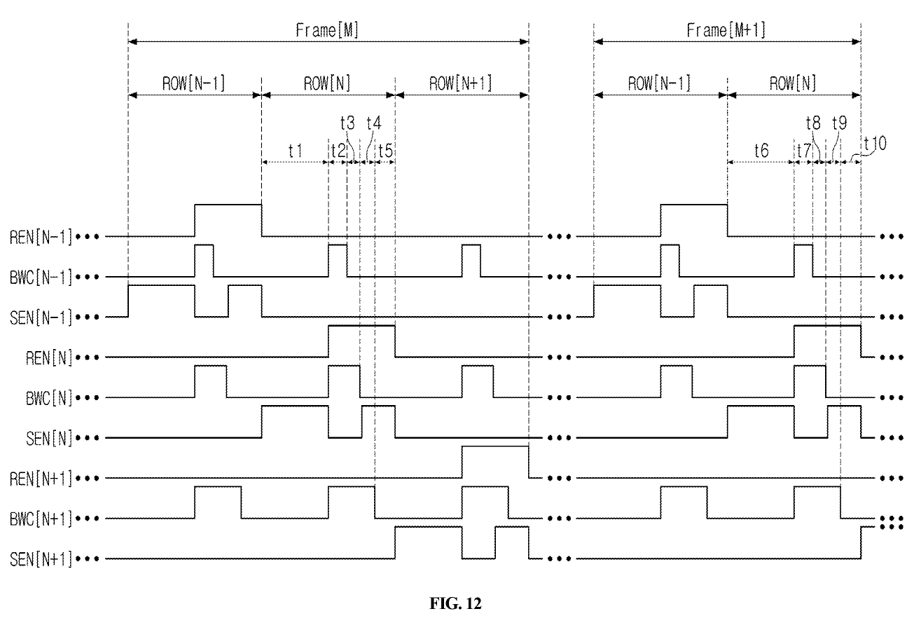

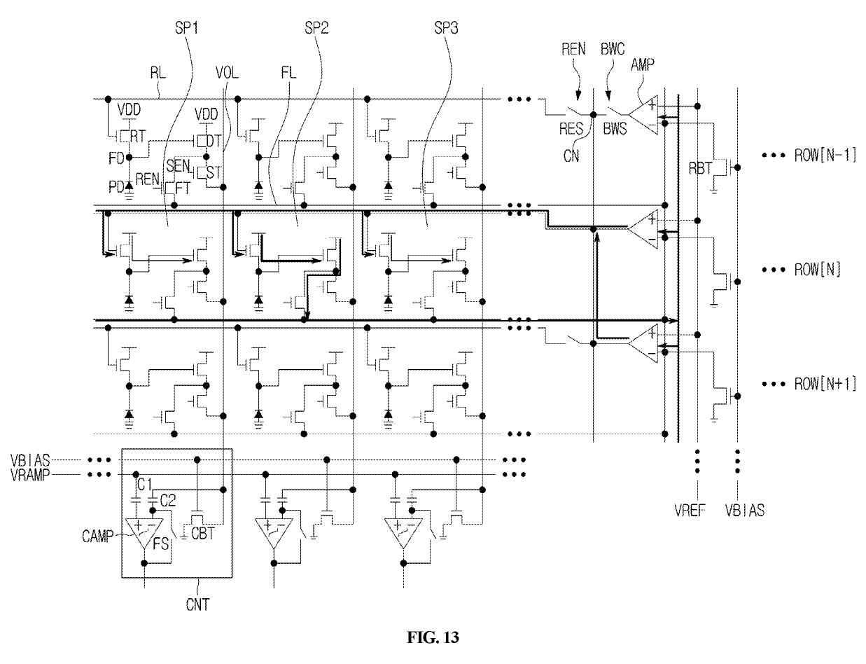

FIG. 12 is a waveform diagram illustrating examples of signals applied to the row feedback structure of FIG. 9, and FIG. 13 is a diagram illustrating a row feedback process according to a waveform diagram of FIG. 12. Specifically, FIG. 11 shows the row feedback process performed during the second period t2 of FIG. 12, and FIG. 13 shows the row feedback process performed during the third period t3 of FIG. 12.

Referring to FIGS. 12 and 13, the pixels SP may detect the light sequentially per row. The pixels SP of each of the (N-1)th row ROW[N-1], the Nth row ROW[N], and the (N+1)th row ROW[N+1] may detect the light sequentially. After the pixels SP in all rows detect the light during the Mth frame Frame[M], the pixels SP in all rows may detect the light during the (M+1)th frame Frame[M+1].

The first to fifth periods t1, t2, t3, t4, and t5 may be sequentially performed during the Mth frame Frame[M], and the sixth to tenth periods t6, t7, t8, t9, and t10 may be sequentially performed during the (M+1)th frame Frame[M+1].

The selection transistor ST of each of the pixels SP of the Nth row ROW[N] may receive a high-level selection signal SEN[N] during the first, fourth and fifth periods t1, t4 and t5. The selection transistor ST may be turned on during the first period t1 to perform readout and sample the output voltage. The selection transistor ST may be turned on during the fourth and fifth periods t4 and t5 to sample the reset voltage of the floating diffusion region FD.

The feedback transistor FT of each of the pixels of the Nth row ROW[N] may receive a high-level row enable signal REN[N] during the second, third, fourth, and fifth periods t2, t3, t4 and t5. The feedback transistor FT may be turned on during the second to fifth periods t2, t3,t4 and t5, and transmit the feedback voltage to the feedback signal line FL. The pixels SP arranged in the same row may be electrically connected to the same feedback signal line FL. The feedback signal line FL may carry the feedback signal representing the highest voltage of the floating diffusion region FD among the pixels SP of the Nth row ROW[N].

The bandwidth control switches BWS arranged in the plurality of rows may be turned on simultaneously during the second period t2, and may be turned off sequentially thereafter. For example, as illustrated in FIG. 11, the bandwidth control switch BWS of each of the pixels SP of the N-1th row ROW[N-1], the Nth row ROW[N], the N+1th row ROW[N+1] may receive a high-level bandwidth control signal BWC[N-1], BWC[N], and BWC[N+1] during the second periodt2. The bandwidth control switches BWS of the (N-1)th row ROW[N-1], the Nth row ROW[N], the (N+1)th row ROW[N+1] may be turned on during the second period t2 and may transmit the output of the feedback amplifiers AMP to the column connection node CN. During the second period t2, at least one feedback process may be performed, and the voltage of the floating diffusion region FD of some pixels SP may approach the reference voltage VREF.

For example, as illustrated in FIG. 13, the bandwidth control switch BWS of each of the pixels SP of the Nth row ROW[N], and the (N+1)th row ROW[N+1] may receive a high-level bandwidth control signals BWC[N] and BWC[N+1] during the third period t3. The bandwidth control switches BWS of the Nth row ROW[N], and the (N+1)th row ROW[N+1] may be turned on during the third period t3 and may transmit the output of the feedback amplifiers AMP to the column connection node CN. The reset process of some pixels SP has been performed during the second period t2, and therefore, a fewer number of feedback amplifies AMP than those of the second period t3 may be used in the third period t3. At least one feedback process may be performed during the third period t3, and the voltage of the floating diffusion region FD of some other pixels SP may approach the reference voltage VREF.

For example, the bandwidth control switch BWS of the (N+1)th row ROW[N+1] may receive a high-level bandwidth control signal BWC[N+1] during the fourth period t4. The bandwidth control switch BWS of the (N+1)th row ROW[N+1] may be turned on during the fourth period t4, and may transmit the output of the feedback amplifiers AMP to the column connection node CN. The reset process of some pixels SP has been performed during the second and third periods t2 and t3, and therefore, a fewer number of feedback amplifies AMP than those of the second period t3 may be used during the fourth period t4. At least one feedback process may be performed during the fourth period t4, and the voltage of the floating diffusion region FD of some other pixels SP may approach the reference voltage VREF.

The reset enable switch RES of the Nth row ROW[N] may be turned on based on the row enable signal REN[N]. The reset enable switch RES may electrically connect the column connection node CN to the reset signal line RL of the Nth row ROW[N]. Therefore, the reset enable switch RES may select the Nth row ROW[N] among the plurality of rows and may form the negative feedback loop. The output of the feedback amplifiers AMP may be transmitted to the reset signal line RL through the column connection node CN and the reset enable switch RES.

The image sensing device 100 may achieve a sufficient amplifier gain by performing the feedback process through a plurality of feedback amplifiers AMP, even when a large number of pixels SP are arranged in a single row. This configuration may prevent degradation of the negative feedback effect caused by the bandwidth limitation due to amplifier shortages. The image sensing device 100 may reset the voltage of the floating diffusion region FD of all pixels SP in the same row to the reference voltage VREF, and the voltage gap of the floating diffusion regions FD of the pixels SP may be minimized.

In addition, the image sensing device 100 may progressively reduce the number of the feedback amplifiers AMP in operation as the feedback process progresses. The image sensing device 100 may decrease the power consumption and reduce the bandwidth sequentially by decreasing the number of the feedback amplifiers AMP in operation sequentially. Therefore, the image sensing device 100 may separately remove noise from a high-frequency noise component to a low-frequency noise component. The image sensing device 100 may remove the reset noise or kTC noise of the pixels SP, and at the same time, may reduce the power consumption effectively.

The disclosed technology can be implemented in various embodiments to provide the image sensing device 100 and the imaging device 10 as will be described below.

In an embodiment, an image sensing device includes: a plurality of first pixels configured to convert light into photocharge and arranged in a first row of a pixel array; a first feedback signal line configured to transmit a feedback signal from the first pixels; a first feedback amplifier configured to compare the feedback signal received from the first feedback signal line with a reference voltage and output a reset signal; and a first reset signal line configured to transmit the reset signal to the first pixels.

In the image sensing device based on various embodiments of the disclosed technology, each of the first pixels may include: a photodetector configured to convert light into photocharge; a floating diffusion region configured to receive the electric charge accumulated in the photodetector; a reset transistor configured to transmit a power supply voltage to the floating diffusion region in response to the reset signal; a driver transistor configured to be turned on based on a voltage of the floating diffusion region; a selection transistor configured to electrically connect the driver transistor to an output signal line; and a feedback transistor configured to electrically connect the driver transistor to the first feedback signal line.

The image sensing device based on various embodiments of the disclosed technology may further include: a first bandwidth control switch configured to electrically connect an output terminal of the first feedback amplifier to the first reset signal line in response to a bandwidth control signal.

In the image sensing device based on various embodiments of the disclosed technology, the selection transistor may be turned on during a first period and a third period, the feedback transistor and the bandwidth control switch may be turned on during a second period and the third period, and the first to third periods may be sequentially performed during an Mth frame, wherein M is a positive integer.

In the image sensing device based on various embodiments of the disclosed technology, the selection transistor may be turned on during a fourth period and a sixth period, the feedback transistor and the bandwidth control switch may be turned on during a fifth period and a sixth period, and the fourth to sixth periods may be sequentially performed during an (M+1)th frame.

In the image sensing device based on various embodiments of the disclosed technology, the floating diffusion region may have a feedback reset period in the second period and the third period, and have a photocharge accumulation period staring from an end of the third period and lasting until an end of the fourth period.

The image sensing device based on various embodiments of the disclosed technology may further include: a row bias transistor configured to connect the first feedback signal line to ground based on a bias voltage.

The image sensing device based on various embodiments of the disclosed technology may further include: a first capacitor including a first electrode configured to receive a ramp voltage; a second capacitor including a first electrode electrically connected to the output signal line; a column amplifier including a first input terminal electrically connected to a second electrode of the first capacitor and a second input terminal electrically connected to a second electrode of the second capacitor; and a column bias transistor configured to connect the output signal line to ground based on a bias voltage.

The image sensing device based on various embodiments of the disclosed technology may further include: a plurality of second pixels arranged in a second row of the pixel array adjacent to the first row; a second feedback signal line configured to transmit a feedback signal of the second pixels; a second feedback amplifier configured to compare a feedback signal received from the second feedback signal line with a reference voltage and output a reset signal; and a second reset signal line configured to output the reset signal to the second pixels.

In the image sensing device based on various embodiments of the disclosed technology, each of the first and second reset signal lines may transmit a reset signal to each of the first and second pixels simultaneously.

In another embodiment, an image sensing device includes: a plurality of first pixels arranged in a first row in a pixel array; a first feedback signal line configured to transmit a feedback signal from the plurality of first pixels; a first feedback amplifier configured to compare a feedback signal received from the first feedback signal line with a reference voltage and output a first reset signal; a first bandwidth control switch electrically connected to an output terminal of the first feedback amplifier; a first reset signal line configured to transmit the first reset signal to the plurality of first pixels; a plurality of second pixels disposed in a second row of the pixel array adjacent to the first row; a second feedback signal line configured to deliver a feedback signal of the second pixels; a second feedback amplifier configured to compare a feedback signal received from the second feedback signal line with a reference voltage and output a second reset signal; a second bandwidth control switch electrically connected to an output terminal of the second feedback amplifier; a second reset signal line configured to transmit the second reset signal to the second pixels; and a column connection node configured to electrically connect the first bandwidth control switch to the second bandwidth control switch.

In the image sensing device based on various embodiments of the disclosed technology, each of the first pixels may include: a photodetector configured to convert light into photocharge; a floating diffusion region configured to receive the electric charge accumulated in the photodetector; a reset transistor configured to transmit a power supply voltage to the floating diffusion region in response to the first reset signal; a driver transistor configured to be turned on based on a voltage of the floating diffusion region; a selection transistor configured to electrically connect the driver transistor to an output signal line; and a feedback transistor configured to electrically connect the driver transistor to the first feedback signal line, and each of the second pixels may include: a photodetector configured to convert light into photocharge; a floating diffusion region configured to receive the electric charge accumulated in the photodetector; a reset transistor configured to transmit a power supply voltage to the floating diffusion region in response to the second reset signal; a driver transistor configured to be turned on based on a voltage of the floating diffusion region; a selection transistor configured to electrically connect the driver transistor to an output signal line; and a feedback transistor configured to electrically connect the driver transistor to the second feedback signal line.

The image sensing device based on various embodiments of the disclosed technology may further include: a first reset enable switch configured to electrically connect the column connection node to the first reset signal line; and a second reset enable switch configured to electrically connect the column connection node to the second reset signal line.

In the image sensing device based on various embodiments of the disclosed technology, the selection transistor of the first pixels may be turned on during a first period and a third period, the feedback transistor of the first pixels may be turned on during a second period and the third period, the first bandwidth control switch and the second bandwidth control switch may be turned on during the second period and the third period, and the first to third periods may be sequentially performed during an Mth frame, wherein M is a positive integer.

In the image sensing device based on various embodiments of the disclosed technology, the selection transistor of the first pixels may be turned on during a first period, a fourth period and a fifth period, the feedback transistor of the first pixels may be turned on during a second period, a third period, the fourth period, and the fifth period, the first bandwidth control switch may be turned on during the second period and the third period, the second bandwidth control switch may be turned on during the second period to the fourth period, and the first to fifth periods may be sequentially performed during an Mth frame, wherein M is a positive integer.

In the image sensing device based on various embodiments of the disclosed technology, a first input terminal of each of the first and second feedback amplifiers may receive a reference voltage, and a second input terminal of each of the first and second feedback amplifiers may be electrically connected to the first and second feedback signal lines.

The image sensing device based on various embodiments of the disclosed technology may further include: a first row bias transistor configured to connect the first feedback signal line to ground based on a bias voltage, and a second row bias transistor configured to connect the second feedback signal line to ground based on the bias voltage.

The image sensing device based on various embodiments of the disclosed technology may further include: a first capacitor including a first electrode configured to receive a ramp voltage; a second capacitor including a first electrode electrically connected to the output signal line; a column amplifier including a first input terminal electrically connected to a second electrode of the first capacitor and a second input terminal electrically connected to a second electrode of the second capacitor; and a column bias transistor configured to connect the output signal line to ground based on a bias voltage.

In another embodiment, an imaging device includes: an image sensing device configured to convert an optical signal into an electric signal and generate image data; and an image signal processor (ISP) configured to image signal process the image data, and the image sensing device may include: a plurality of first pixels configured to convert light into photocharge and arranged in a first row of a pixel array; a first feedback signal line configured to transmit a feedback signal from the first pixels; a first feedback amplifier configured to compare a feedback signal received from the first feedback signal line with a reference voltage and output a reset signal; and a first reset signal line configured to transmit the reset signal to the first pixels.

In the imaging device based on various embodiments of the disclosed technology, each of the first pixels may include: a photodetector configured to convert light into photocharge; a floating diffusion region configured to receive the electric charge accumulated in the photodetector; a reset transistor configured to transmit a power supply voltage to the floating diffusion region based on the reset signal; a driver transistor configured to be turned on based on a voltage of the floating diffusion region; a selection transistor configured to electrically connect the driver transistor to an output signal line; and a feedback transistor configured to electrically connect the driver transistor to the first feedback signal line.

Only a few implementations and examples of the disclosed technology are described and other implementations, enhancements and variations can be made based on what is described and illustrated in this patent document.

What is claimed is:

1. An image sensing device, comprising:
a plurality of first pixels configured to convert light into photocharge and arranged in a first row of a pixel array;
a first feedback signal line coupled to the plurality of first pixels in the first row of the pixel array and configured to transmit a feedback signal from the plurality of first pixels;
a first feedback amplifier coupled to the first feedback signal line to receive the feedback signal and configured to: compare the feedback signal received from the first feedback signal line with a reference voltage; and output a reset signal; and
a first reset signal line coupled to the plurality of first pixels in the first row of the pixel array and configured to transmit the reset signal to the plurality of first pixels.

2. The image sensing device of claim 1,
wherein each of the first pixels comprises:
a photodetector configured to convert light into photocharge;
a floating diffusion region coupled to the photodetector and configured to receive the photocharge from the photodetector;
a reset transistor coupled to the floating diffusion region and configured to transmit a power supply voltage to the floating diffusion region in response to the reset signal;
a driver transistor coupled to the floating diffusion region and an output signal line and configured to be turned on based on a voltage of the floating diffusion region;
a selection transistor coupled to the driver transistor and configured to electrically couple the driver transistor to the output signal line coupled to the driver transistor; and
a feedback transistor coupled to the driver transistor and configured to electrically couple the driver transistor to the first feedback signal line.

3. The image sensing device of claim 2, further comprising:
a first bandwidth control switch configured to electrically connect an output terminal of the first feedback amplifier to the first reset signal line in response to a bandwidth control signal.

4. The image sensing device of claim 3,
wherein the selection transistor is turned on during a first period and a third period, the feedback transistor and the bandwidth control switch are turned on during a second period and the third period, and the first to third periods are sequentially performed during an Mth frame, wherein M is a positive integer.

5. The image sensing device of claim 4,
wherein the selection transistor is turned on during a fourth period and a sixth period, the feedback transistor and the bandwidth control switch are turned on during a fifth period and a sixth period, and the fourth to sixth periods are sequentially performed during an (M+1)th frame.

6. The image sensing device of claim 5,
wherein the floating diffusion region has a feedback reset period during the second period and the third period, and has a photocharge accumulation period starting from an end of the third period ends and lasting until an end of the fourth period.

7. The image sensing device of claim 1, further comprising:
a row bias transistor configured to connect the first feedback signal line to ground based on a bias voltage.

8. The image sensing device of claim 1, further comprising:
a first capacitor including a first electrode configured to receive a ramp voltage;
a second capacitor including a first electrode electrically connected to an output signal line;
a column amplifier including a first input terminal electrically connected to a second electrode of the first capacitor and a second input terminal electrically connected to a second electrode of the second capacitor; and
a column bias transistor configured to connect the output signal line to ground based on a bias voltage.

9. The image sensing device of claim 1, further comprising:
a plurality of second pixels arranged in a second row of the pixel array adjacent to the first row;
a second feedback signal line configured to transmit a feedback signal of the second pixels;
a second feedback amplifier configured to: compare a feedback signal received from the second feedback signal line with a reference voltage; and output a reset signal; and
a second reset signal line configured to output the reset signal to the second pixels.

10. The image sensing device of claim 9,
wherein each of the first and second reset signal lines transmits a reset signal to each of the first and second pixels simultaneously.

11. An image sensing device, comprising:
a plurality of first pixels configured to convert light into photocharge and arranged in a first row of a pixel array;
a first feedback signal line coupled to the plurality of first pixels in the first row of the pixel array and configured to transmit a feedback signal from the plurality of first pixels;
a first feedback amplifier coupled to the first feedback signal line to receive the feedback signal and configured to: compare the feedback signal received from the first feedback signal line with a reference voltage; and output a first reset signal;
a first bandwidth control switch electrically connected to an output terminal of the first feedback amplifier;
a first reset signal line coupled to the first bandwidth control switch and the first pixels, and configured to transmit the first reset signal from the first feedback amplifier to the first pixels;
a plurality of second pixels configured to convert light into photocharge and disposed in a second row of the pixel array adjacent to the first row;
a second feedback signal line coupled to the plurality of second pixels in the second row of the pixel array and configured to transmit a feedback signal from the second pixels;
a second feedback amplifier coupled to the second feedback signal line to receive the feedback signal from the second pixels and configured to compare the feedback signal received from the second feedback signal line with a reference voltage and output a second reset signal;
a second bandwidth control switch electrically connected to an output terminal of the second feedback amplifier;
a second reset signal line coupled to the second bandwidth control switch and the second pixels, and configured to transmit the second reset signal to the second pixels; and
a column connection node configured to electrically couple the first bandwidth control switch to the second bandwidth control switch.

12. The image sensing device of claim 11,
wherein each of the first pixels comprises:
a photodetector configured to convert light into photocharge;
a floating diffusion region configured to receive the electric charge accumulated in the photodetector;
a reset transistor configured to transmit a power supply voltage to the floating diffusion region in response to the first reset signal;
a driver transistor configured to be turned on based on a voltage of the floating diffusion region;
a selection transistor configured to electrically connect the driver transistor to an output signal line; and
a feedback transistor configured to electrically connect the driver transistor to the first feedback signal line, and
wherein each of the second pixels comprises:
a photodetector configured to convert light into photocharge;
a floating diffusion region configured to receive the electric charge accumulated in the photodetector;
a reset transistor configured to apply a power supply voltage to the floating diffusion region in response to the second reset signal;
a driver transistor configured to be turned on based on a voltage of the floating diffusion region;
a selection transistor configured to electrically connect the driver transistor to an output signal line; and
a feedback transistor configured to electrically connect the driver transistor to the second feedback signal line.

13. The image sensing device of claim 12, further comprising:
a first reset enable switch configured to electrically connect the column connection node to the first reset signal line; and
a second reset enable switch configured to electrically connect the column connection node to the second reset signal line.

14. The image sensing device of claim 13,
wherein the selection transistor of the first pixels is turned on during a first period and a third period, the feedback transistor of the first pixels is turned on during a second period and the third period, the first bandwidth control switch and the second bandwidth control switch are turned on during the second period and the third period, and the first to third periods are sequentially performed during an M-th frame, wherein M is a positive integer.

15. The image sensing device of claim 13,
wherein the selection transistor of the first pixels is turned on during a first period, a fourth period and a fifth period, the feedback transistor of the first pixels is turned on during a second period, a third period, the fourth period, and the fifth period, the first bandwidth control switch is turned on during the second period and the third period, the second bandwidth control switch is turned on during the second period to the fourth period, and the first to fifth periods are sequentially performed during an Mth frame, wherein M is a positive integer.

16. The image sensing device of claim 11,
wherein a first input terminal of each of the first and second feedback amplifiers receives a reference voltage, and
wherein a second input terminal of each of the first and second feedback amplifiers is electrically connected to the first and second feedback signal lines.

17. The image sensing device of claim 11, further comprising:
a first row bias transistor configured to electrically connect the first feedback signal line to ground based on a bias voltage, and
a second row bias transistor configured to electrically connect the second feedback signal line to ground based on the bias voltage.

18. The image sensing device of claim 11, further comprising:
a first capacitor including a first electrode configured to receive a ramp voltage;
a second capacitor including a first electrode electrically connected to an output signal line;
a column amplifier including a first input terminal electrically connected to a second electrode of the first capacitor and a second input terminal electrically connected to a second electrode of the second capacitor; and
a column bias transistor configured to electrically connect the output signal line to ground based on a bias voltage.

19. An imaging device, comprising:
an image sensing device configured to convert an optical signal into an electrical signal and generate image data; and
an image signal processor (ISP) configured to process the image data, and
wherein the image sensing device comprises:
a plurality of first pixels configured to convert light into photocharge and arranged in a first row of a pixel array;
a first feedback signal line configured to transmit a feedback signal from the plurality of first pixels;
a first feedback amplifier configured to: compare the feedback signal received from the first feedback signal line with a reference voltage; and output a reset signal; and
a first reset signal line configured to transmit the reset signal to the first pixels.

20. The imaging device of claim 19,
wherein each of the first pixels comprises:
a photodetector configured to convert light into photocharge;
a floating diffusion region configured to receive the electric charge accumulated in the photodetector;
a reset transistor configured to transmit a power supply voltage to the floating diffusion region based on the reset signal;
a driver transistor being turned on based on a voltage of the floating diffusion region;
a selection transistor configured to electrically connect the driver transistor to an output signal line; and
a feedback transistor configured to electrically connect the driver transistor to the first feedback signal line.
